(19) United States
(12) Patent Application Publication
(10) Pub. No.: US 2002/0160575 A1
(43) Pub. Date: Oct. 31, 2002

(54) High coupling ratio stacked-gate flash memory and the method of making the same

(76) Inventor: Horng-Huei Tseng, Hsinchu (TW)

Correspondence Address: Chun M. Ng, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/846,468

(22) Filed: Apr. 30, 2001

(51) Int. Cl. H01L 21/336

(52) U.S. Cl. 438/298; 438/286

(57) ABSTRACT

A stacked-gate flash memory cell includes a trench formed in a substrate and a tunneling oxide is formed on the substrate. A first part of the floating gate is formed on the tunneling dielectric layer. A protruding isolation filler is formed in the trench and protruding over the upper surface of the first part of the floating gate, thereby forming a cavity between the two adjacent raised isolation filler. A second part of the floating gate is formed along the surface of the cavity to have a U-shaped structure in cross sectional view. A dielectric layer is conformally formed on the surface of the second part of the floating gate and a control gate is formed on the dielectric layer.

The present invention relates to a semiconductor device, and more specifically, to a flash memory having high coupling ratio and the method of fabricating the nonvolatile memory.

### BACKGROUND OF THE INVENTION

The semiconductor industry has been advanced to the field of Ultra Large Scale Integrated (ULSI) technologies. The fabrication of the nonvolatile memories also follows the trend of the reduction of the size of a device. The high-density nonvolatile memories can be applied as the mass storage of portable handy terminals, solid state camera and PC cards. That is because that the nonvolatile memories exhibit many advantages, such as a fast access time, low power dissipation, and robustness. Further, it can be used to replace magnetic disk memory. The nonvolatile memories include various types of devices, such as EAROM (electrically alterable read only memory), EEPROM (electrically erasable programmable read only memory), EEPROM-EAROMs and non-volatile SRAMs.

Different types of devices have been developed for specific applications requirements in each of the segments of memory. In the device, electrical alterability is achieved by Fowler-Nordheim tunneling which is cold electron tunneling through the energy barrier at a silicon-thin dielectric interface and into the oxide conduction band. Typically, the thin dielectric layer is composed of silicon dioxide and the thin silicon dioxide layer allows charges to tunnel through when a voltage is applied to the gate. These charges are trapped in the silicon dioxide and remain trapped there since the materials are high quality insulators. A conventional flash memory is a type of erasable programmable read-only memory (EPROM). One of the advantages of flash memory is its capacity for block-by-block memory erasure. Furthermore, the speed of memory erasure is fast. For other EPROM, the memory erasure can take up to several minutes due to the erase mode of such type memory is done by bit-by-bit.

Various flash memories have been disclosed in the prior art, the type of the flash includes separated-gate and stacked-gate structure. U.S. Pat. No. 6,180,454 to Chang, et al, entitled “Method for forming flash memory devices”, and filed on Oct. 29, 1999. A further U.S. Pat. No. 6,153,906 to Chang, filed on Dec. 8, 1998. The device includes an oxide layer on a substrate. A stacked gate is formed on the substrate. A tunnel diffusion region is formed in the substrate next to a first side of the stacked gate. The tunnel diffusion region extends to a portion of the substrate under the stacked gate. A doped region is formed in the substrate next to a second side of the stacked gate. The doped region is distant away from the stacked gate by a lateral distance. U.S. Pat. No. 5,956,268 disclosed a Nonvolatile memory structure. The prior art allows for array, block erase capabilities.

U.S. Pat. No. 6,153,494 to Hsieh, et al., entitled “Method to increase the coupling ratio of word line to floating gate by lateral coupling in stacked-gate flash” and filed on Feb. 11, 1998. The object of this invention is to provide a method of forming a stacked-gate flash memory having a shallow trench isolation with a high-step in order to increase the lateral coupling between the word line and the floating gate. Hsieh disclosed a step of forming nitride layer and then forming hallow trench isolation (STI) through the nitride layer into the substrate. Then, oxide is filled into the STI, the nitride is then removed leaving behind a deep opening about the filled STI. The detailed description may refer to the prior art. A stacked-gate flash memory cell is provided having a shallow trench isolation with a high-step of oxide and high lateral coupling.

### SUMMARY OF THE INVENTION

The object of the present invention is to form flash memory with higher coupling ratio.

It is another object of this invention to provide a method of forming a stacked-gate flash memory having sidewall coupling to increase the coupling ratio between the control gate and the floating gate of the cell.

The stacked-gate flash memory cell includes a trench formed in a substrate and a tunneling oxide is formed on the substrate. A first part of the floating gate is formed on the tunneling oxide. A raised isolation filler is formed in the trench and protruding over the upper surface of the first part of the floating gate, thereby forming a cavity between the two adjacent raised isolation filler. A second part of the floating gate is formed along the surface of the cavity to have a U-shaped structure in cross sectional view. A dielectric layer is conformally formed on the surface of the second part of the floating gate and a control gate is formed on the dielectric layer.

The method comprises forming a first dielectric layer on a semiconductor substrate as a tunneling dielectric and forming a first conductive layer and a sacrificed layer on the first dielectric layer. Next step is to pattern the sacrificed layer, the first dielectric layer, the first conductive layer and the substrate to form a trench in the substrate. An isolation is refilled into the trench, a portion of isolation is removed to a surface of the sacrificed layer. The sacrificed layer is then removed, thereby forming a cavity between adjacent isolations. A second conductive layer is formed along a surface of the cavity and the isolation. Next, a portion of the second conductive layer is removed to a surface of the isolation. Subsequently, a second dielectric layer is formed on a surface of the floating gate, a third conductive layer is formed on the second dielectric layer as a control gate.

### BRIEF DESCRIPTION OF THE INVENTION

The foregoing aspects and many of the attendant advantages of this invention will become more readily appreciated as the same becomes better understood by reference to the following detailed description, when taken in conjunction with the accompanying drawings, wherein:

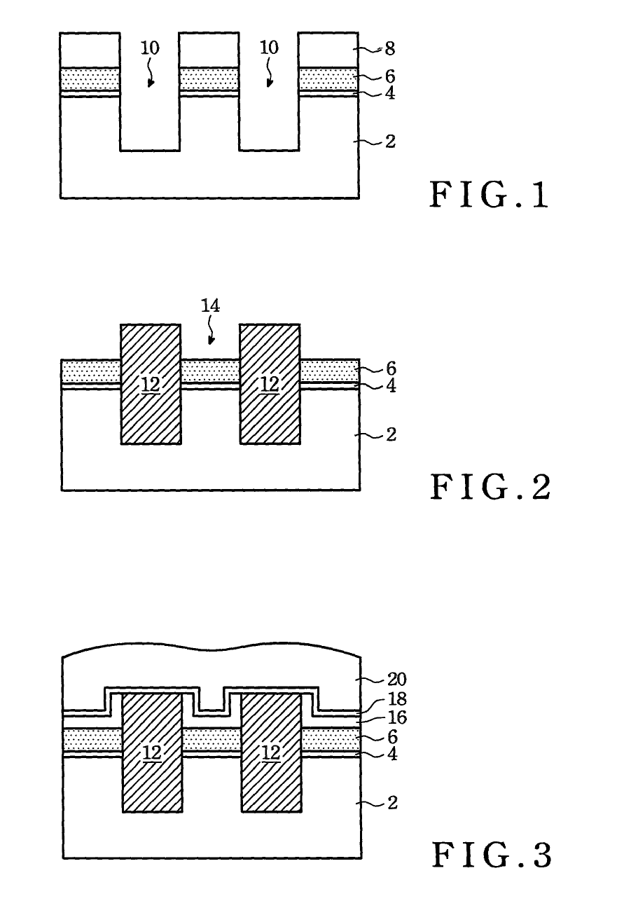

FIG. 1 is a cross section view of a semiconductor wafer illustrating the steps of forming a trench in a substrate according to the present invention.

FIG. 2 is a cross section view of a semiconductor wafer illustrating the step of forming protruding isolation according to the present invention.

FIG. 3 is a cross section views of a semiconductor wafer illustrating the step of defining a control gate according to the present invention.

### DETAILED DESCRIPTION OF THE PREFERRED EMBODIMENT

The present invention proposes a novel structure and method to fabricate the stacked-gate flash memory. The stacked-gate flash memory cell includes a trench formed in a substrate 2, please refer to FIG. 3. A tunneling oxide 4 is formed on the surface of the substrate 2 and adjacent to the trench 4. A first part of the floating gate 6 is formed on the tunneling gate oxide 4. A protruding isolation (filler) 10 is formed in the trench and protruding over the upper surface of the first part of the floating gate 6, thereby forming a cavity 14 between the adjacent protruding isolation filler 10. A second part of the floating gate 16 is formed along the surface of the cavity 14 to have a U-shaped structure in cross sectional view. The high level of the U-shaped structure is the same with the one of the protruding isolation filler 10. A dielectric layer 18 is conformally formed on the surface of the second part of the floating gate 16 and a control gate is formed on the dielectric layer 20.

The method of forming the structure is described as follows. In the method, a trench is formed and a floating gate is formed in the trench to increase the coupling ratio. The detail description of the method will be seen as follows. In a preferred embodiment, as shown in the FIG. 1, a single crystal silicon substrate 2 with a <100>or <111>crystallographic orientation is provided. A dielectric such as oxide layer 4 is formed on the substrate 2 as tunneling dielectric layer. Typically, the oxide 4 can be grown in oxygen ambient in a furnace at a temperature of about 800 to 1100 degrees centigrade. The thickness of the silicon oxide layer 4 is about 50 to 500 angstroms. Other method, such as chemical vapor deposition, can be used to form the oxide 4. It is appreciated that any suitable material such as silicon oxynitride may be used as the gate dielectric. Preferably, the silicon oxynitride layer is formed by thermal oxidation in N₂O or NO environment. The temperature for forming the silicon oxynitride layer 4 ranges from 700 to 1150 degrees centigrade.

Next, as can be seen by reference to FIG. 1, a conductive layer, such as doped polysilicon layer 6, is formed on the oxide layer 4. The doped polysilicon layer 6 can be chosen from doped polysilicon or in-situ doped polysilicon. This is achieved preferably through a LPCVD method employing silane as a silicon source material at a temperature range between about 500 to 650 degree C. The thickness of the polysilicon is about 2000-6000 angstroms. Next, a sacrificed layer 8 is subsequently formed on the doped polysilicon layer 6. Preferably, the material used to form the sacrificed layer 8 is nitride. The silicon nitride layer 8 is deposited by any suitable process. For example, Low Pressure Chemical Vapor Deposition (LPCVD), Plasma Enhance Chemical Vapor Deposition (PECVD), High Density Plasma Chemical Vapor Deposition (HDPCVD). In the preferred embodiment, the reaction gases of the step to form silicon nitride layer include SiH₄, NH3, N₂ or SiH₂Cl₂, NH₃, N₂.

A photoresist is patterned on the sacrificed layer 8 to define trench region, followed by etching the stacked layer consisting of the sacrificed layer 8, the polysilicon layer 6, dielectric layer 4 and the substrate 2 to form trenches 10 in the substrate 2. The photoresist is next removed by oxygen plasma ashing. Subsequently, the trench 10 is filled with isolation oxide 12, using the method of high density plasma (HDP) deposition or LPCVD. Next, the substrate 2 is subjected to chemical-mechanical polishing (CMP), thus forming shallow trench isolation (STI) 12 as shown in FIG. 2. Then, the sacrificed layer 8 is removed by hot phosphorus acid solution, thereby forming protruding isolation filler 12 protruding over the surface the polysilicon 6. A cavity 14 is therefore formed between the raised isolation filler 10. The step high of the protruding isolation filler 12 can be defined by the thickness of the sacrificed layer 8. Hence, the coupling ratio can be controlled by the present invention.

Next, a thin conductive layer 16 such as in-situ doped polysilicon along the surface of the cavity 14 and the protruding isolation filler 12. The thickness of the thin conductive layer is about 100-1000 angstroms. Next, the thin conductive layer 16 is removed to expose the upper surface of the protruding isolation filler 12 by CMP. The thin polysilicon layer 16 only remains on side wall and bottom of the cavity 14, as shown in FIG. 3.

The polysilicon layer 6 and the remained thin polysilicon layer 16 serve as a floating gate and isolated by the protruding isolation filler 12. As another key aspect of the present invention, remained thin polysilicon layer 16 is conformally formed so as to follow the contours of the cavity 14, thus providing additional surface to the control gate dielectric that is to be formed later. In another words, the polysilicon should not fill the totally the cavity 14.

An interpoly dielectric layer 18 is next formed over the contours of the conformal floating gate and the upper surface of the protruding isolation filler 12, as shown in FIG. 3.

It is preferred that the interpoly dielectric layer 18 comprises but not limited to oxide/nitride/oxide (ONO), ON. Then, a further polysilicon layer 20 is formed over the interpoly dielectric layer 18 to act as the control gate and word line. Thus, a stacked-gate flash is formed as shown in the cross-sectional view of FIG. 3. A further patterning may be used to define the control gate.

The higher coupling can be obtained due to the floating gate formed against the high-step oxide protruding over the isolation trench of the present invention.

It has to be noted that the first conductive layer 6 can be omitted and to increase the thickness of the sacrificed layer 8 in order increase the coupling surface. After the isolation 12 is formed, followed by removing the entire sacrificed layer 8. The following sequences are similar to the aforementioned embodiment to deposit the conductive layer 16, polish the layer 16 and to form the ONO 18, the control gate 20.

The stacked-gate flash memory cell includes trenches formed in a substrate 2, a tunneling oxide 4 is formed on the surface of the substrate 2 and adjacent to the trench 4. A protruding isolation (filler) 10 is formed in the trench and protruding over the upper surface of the tunneling oxide 4, thereby forming a cavity 14 between the adjacent protruding isolation filler 10. A floating gate 16 is formed along the surface of the cavity 14 to have a U-shaped structure in cross sectional view. The high level of the U-shaped structure is the same with the one of the protruding isolation filler 10. A dielectric layer 18 is conformally formed on the surface of the second part of the floating gate 16 and a control gate is formed on the dielectric layer 20.

As will be understood by persons skilled in the art, the foregoing preferred embodiment of the present invention is illustrative of the present invention rather than limiting the present invention. Having described the invention in connection with a preferred embodiment, modification will now suggest itself to those skilled in the art. Thus, the invention is not to be limited to this embodiment, but rather the invention is intended to cover various modifications and similar arrangements included within the spirit and scope of the appended claims, the scope of which should be accorded the broadest interpretation so as to encompass all such modifications and similar structures.

While the preferred embodiment of the invention has been illustrated and described, it will be appreciated that various changes can be made therein without departing from the spirit and scope of the invention.

What is claimed is:

1. A stacked-gate flash memory comprising:
a substrate having trenches formed therein;
a tunneling oxide formed on a surface of said substrate and adjacent to said trenches;
raised isolation fillers formed in said trenches and protruding over an upper surface of said substrate, thereby forming a cavity between two adjacent raised isolation fillers;
a floating gate formed along a surface of said cavity to have a U-shaped structure in cross sectional view, wherein the high level of said U-shaped structure is the same with the one of said raised isolation fillers;
a dielectric layer conformally formed on a surface of said floating gate; and
a control gate formed on said dielectric layer.

2. The stacked-gate flash memory of claim 1, wherein said raised isolation filler includes oxide.

3. The stacked-gate flash memory of claim 1, wherein said first part of said floating gate includes polysilicon.

4. The stacked-gate flash memory of claim 1, wherein said second part of said floating gate includes polysilicon.

5. The stacked-gate flash memory of claim 1, wherein said dielectric layer includes oxide/nitride/oxide.

6. The stacked-gate flash memory of claim 1, wherein said dielectric layer includes oxide/nitride.

7. A method of manufacturing a stacked-gate flash memory, comprising:
forming a first dielectric layer on a semiconductor substrate as a tunneling dielectric;
forming a first conductive layer on said first dielectric layer;
forming a sacrificed layer on said first conductive layer;
patterning said sacrificed layer, said first dielectric layer, said first conductive layer and said substrate to form trenches in said substrate;
forming isolations into said trenches;
removing said sacrificed layer, thereby forming a cavity between said isolations and said isolations protruding over said first conductive layer;
forming a second conductive layer along a surface of said cavity and said isolation;
removing a portion of said second conductive layer to a surface of said isolation, wherein said second conductive layer and said first conductive layer act as a floating gate;
forming a second dielectric layer on a surface of said floating gate; and
forming a third conductive layer on said second dielectric layer as a control gate.

8. The method of claim 7, wherein said sacrificed layer comprises nitride.

9. The method of claim 8, wherein said sacrificed layer is removed by hot phosphorus acid solution.

10. The method of claim 7, wherein said second conductive layer is removed by chemical mechanical polishing.

11. The method of claim 7, wherein said second dielectric layer comprises oxide/nitride.

12. The method of claim 7, wherein said second dielectric layer comprises oxide/nitride/oxide.
